(19) United States
(12) Patent Application Publication
(10) Pub. No.: US 2026/0271556 A1
(43) Pub. Date: Sep. 10, 2026

(54) DISPLAY APPARATUS AND ELECTRONIC APPARATUS INCLUDING THE SAME

(71) Applicant: Samsung Display Co., Ltd., Yongin-Si (KR)

(72) Inventor: Kwangsoo Lee, Yongin-si (KR)

(21) Appl. No.: 19/325,943

(22) Filed: Sep. 11, 2025

(30) Foreign Application Priority Data
Mar. 6, 2025 (KR) 10-2025-0029198

(51) Int. Cl. H10K 59/131; H10K 59/126

(52) U.S. Cl. CPC H10K 59/131; H10K 59/126

(57) ABSTRACT

Provided are a display apparatus and an electronic apparatus including the same, wherein the display apparatus includes a substrate including a first display area and a second display area, the second display area having a transmission area, first pixel circuits and first display elements in the first display area, second pixel circuits and second display elements on the substrate in the second display area and making up pixel groups that are spaced apart from each other with the transmission area therebetween, a first wiring group and a second wiring group disposed at least partially between the pixel groups in the second display area, and a shielding layer in the second display area and, in a plan view, arranged between the first wiring group and the second wiring group.

### CROSS-REFERENCE TO RELATED APPLICATION

This application is based on and claims priority, under 35 U.S.C. § 119, to Korean Patent Application No. 10-2025-0029198 filed on Mar. 6, 2025 in the Korean Intellectual Property Office, the disclosure of which is incorporated by reference herein in its entirety.

### BACKGROUND

### 1. Field

One or more embodiments relate to a display panel and a display apparatus including the same and, more specifically, to a display apparatus having an expanded display area to be capable of displaying an image even in an area where a component, which is an electronic element, is arranged, and an electronic apparatus including the same.

### 2. Description of Related Art

Display apparatuses are being applied in increasingly diverse ways. In addition, display apparatuses are being manufactured to be thinner and lighter, thereby allowing for a wider range of use.

As display apparatuses are utilized in various ways, various methods may be used to design their forms, and functions that may be integrated or linked with display apparatuses are also increasing.

### SUMMARY

One or more embodiments include a display apparatus having an expanded display area to be capable of displaying an image even in an area that includes a component, which is an electronic element, and an electronic apparatus including the same. However, the embodiments are only examples, and the scope of the disclosure is not limited to the specific embodiments that are depicted.

Additional aspects will be set forth in part in the following description and, in part, will be apparent from the description, or may be learned by practice of the presented embodiments of the disclosure.

According to one or more embodiments, a display apparatus includes a substrate including a first display area and a second display area having a transmission area, first pixel circuits and first display elements in the first display area, second pixel circuits and second display elements on the substrate in the second display area, the second display area, the second pixel circuits and the second display elements being part of pixel groups that are spaced apart from each other with the transmission area therebetween, a first wiring group and a second wiring group disposed at least partially between the pixel groups in the second display area, and a shielding layer in the second display area and, in a plan view, arranged between the first wiring group and the second wiring group.

In an embodiment, the first wiring group and the second wiring group may be connected to demultiplexers that operate according to a first control signal and a second control signal, the first wiring group may include a first data line through which a data signal is transmitted according to the first control signal, and the second wiring group may include a second data line through which a data signal is transmitted according to the second control signal.

In an embodiment, the shielding layer may include a shielding wiring and an upper shielding layer arranged one on top of the other in different layers and are connected to each other via an upper contact hole.

In an embodiment, the shielding wiring may extend in one direction in the second display area, and the upper shielding layer may extend in a direction that is orthogonal to the one direction.

In an embodiment, the upper shielding layer may at least partially overlap the first wiring group and the second wiring group.

In an embodiment, the shielding wiring may include a first shielding line and a second shielding line, the second shielding line being arranged in a different layer from the first shielding line and connected to the first shielding line via a wiring contact hole, wherein the first shielding line may overlap the second shielding line.

In an embodiment, the shielding layer may further include a lower shielding layer arranged under the shielding wiring, and the shielding wiring may be connected to the lower shielding layer via a lower contact hole.

In an embodiment, the upper shielding layer may be arranged in a same layer as pixel electrodes of the second display elements.

In an embodiment, the display apparatus may further include a second-1 planarization layer arranged between the shielding wiring and the upper shielding layer and including an inorganic insulating material, and a second-2 planarization layer covering the upper shielding layer and including an organic insulating material, wherein the pixel electrodes of the second display elements may be arranged on the second-2 planarization layer.

In an embodiment, the display apparatus may further include a second planarization layer arranged between the shielding wiring and the upper shielding layer, wherein the second planarization layer is thinner in an area where the upper shielding layer is arranged than in other areas.

In an embodiment, the shielding layer may include a shielding wiring having a first shielding line and a second shielding line that are arranged one on top of the other in different layers and are connected to each other via a wiring contact hole.

In an embodiment, the shielding layer may further include a lower shielding layer under the shielding wiring, and the second shielding line may be connected to the lower shielding layer via a lower contact hole.

In an embodiment, a constant voltage may be applied to the shielding layer.

In an embodiment, the shielding layer may be provided by a lower shielding layer, a shielding wiring, and an upper shielding layer in an overlapping arrangement wherein the shielding wiring may extend in one direction between the first wiring group and the second wiring group.

In an embodiment, the display apparatus may further include a lower metal layer arranged between the substrate and the second pixel circuits, wherein the lower shielding layer may be integrated with the lower metal layer.

According to one or more embodiments, an electronic apparatus includes a display apparatus, wherein the display apparatus includes a substrate including a first display area and a second display area, the second display area having a transmission area, first pixel circuits and first display elements in the first display area, second pixel circuits and second display elements on the substrate in the second display area, the second pixel circuits and the second display elements being part of pixel groups that are spaced apart from each other with the transmission area therebetween, a first wiring group and a second wiring group, the second wiring group extending between the pixel groups in the second display area, and a shielding layer in the second display area and, in a plan view, arranged between the first wiring group and the second wiring group.

In an embodiment, the shielding layer may be provided by arranging a shielding wiring and an upper shielding layer on top of each other, wherein the shielding wiring may extend in one direction between the first wiring group and the second wiring group.

In an embodiment, the upper shielding layer may extend in a direction orthogonal to the one direction.

In an embodiment, the shielding layer may further include a lower shielding layer arranged under the shielding wiring.

In an embodiment, the first wiring group and the second wiring group may be connected to demultiplexers that operate according to a first control signal and a second control signal, the first wiring group may include a first data line through which a data signal is transmitted according to the first control signal, and the second wiring group may include a second data line through which a data signal is transmitted according to the second control signal.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a perspective view schematically showing a display apparatus according to an embodiment;

FIG. 2 is a cross-sectional view schematically showing a portion of a display apparatus according to an embodiment;

FIG. 3 is a plan view schematically illustrating a display panel that may be included in the display apparatus of FIG. 1;

FIG. 4 is an equivalent circuit diagram of a pixel circuit configured to drive a sub-pixel, according to an embodiment;

FIG. 5 is a layout diagram schematically showing a pixel arrangement structure in a main display area, according to an embodiment;

FIG. 6 is a layout diagram schematically showing a pixel arrangement structure in a component area, according to an embodiment;

FIG. 7 is a schematic cross-sectional view illustrating a portion of a display panel according to an embodiment, including a main display area and a component area;

FIG. 8 is a plan view schematically showing an arrangement relationship of sub-pixels and wirings of a display panel according to an embodiment;

FIG. 9 is a diagram schematically showing an example of wiring groups that receive data signals by a data distribution unit;

FIG. 10 is a cross-sectional view, taken along a line I-I′ of FIG. 8, showing a shielding layer according to an embodiment;

FIG. 11 is a cross-sectional view showing a shielding layer according to an embodiment;

FIG. 12 is a cross-sectional view showing a shielding layer according to an embodiment;

FIG. 13 is a cross-sectional view showing a shielding layer according to an embodiment;

FIG. 14 is a cross-sectional view showing a shielding layer according to an embodiment;

FIG. 15 is a cross-sectional view showing a shielding layer according to an embodiment;

FIG. 16 is a block diagram of an electronic apparatus according to an embodiment; and

FIG. 17 shows schematic views of electronic apparatuses according to various embodiments.

### DETAILED DESCRIPTION

Reference will now be made in detail to embodiments, examples of which are illustrated in the accompanying drawings, wherein like reference numerals refer to like elements throughout the specification. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

Various modifications may be applied to the present embodiments, and particular embodiments will be illustrated in the drawings and described in the detailed description section. The effect and features of the disclosure, and a method to achieve the same, will be clearer referring to the detailed descriptions below with the drawings. However, the present embodiments may be implemented in various forms, not by being limited to the embodiments presented below.

Hereinafter, embodiments of the disclosure will be described in detail with reference to the accompanying drawings, and in the description with reference to the drawings, the same or corresponding components are indicated by the same reference numerals and redundant descriptions thereof are omitted.

In the following embodiment, it will be understood that when a component such as a layer, film, area, or plate is referred to as being “formed on” another layer, film, area, or plate, it can be directly or indirectly formed on the other layer, film, area, or plate. That is, for example, intervening layers, films, areas, or plates may be present. Also, sizes of components in the drawings may be exaggerated for convenience of explanation. In other words, since sizes and thicknesses of components in the drawings are arbitrarily illustrated for convenience of explanation, the following embodiments are not limited thereto.

In the following embodiment, the x-axis, the y-axis, and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

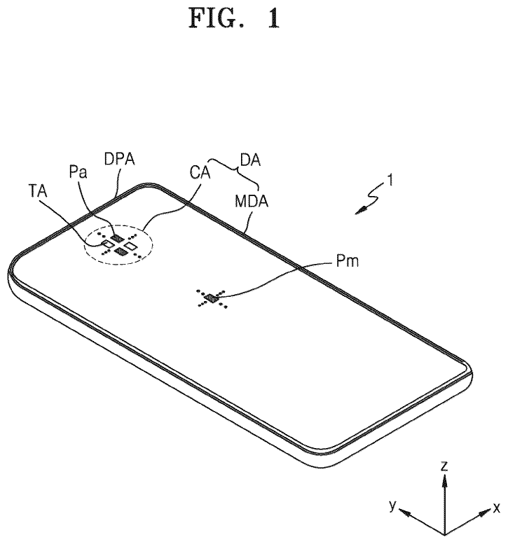

FIG. 1 is a perspective view schematically showing a display apparatus 1 according to an embodiment.

Referring to FIG. 1, the display apparatus 1 includes a display area DA and a peripheral area DPA outside the display area DA. The display area DA includes a component area CA and a main display area MDA that at least partially surrounds the component area CA. The main display area MDA may be referred to as a first display area, and the component area CA may be referred to as a second display area.

The component area CA and the main display area MDA may display images either individually or together. The peripheral area DPA may be a type of non-display area in which no display elements are arranged. The display area DA may be entirely surrounded by the peripheral area DPA.

FIG. 1 shows that one component area CA is arranged in the main display area MDA. In another embodiment, the display apparatus 1 may have two or more component areas CA, and a plurality of component areas CA may have different shapes and sizes from each other. When viewed in a direction approximately perpendicular to a top surface of the display apparatus 1, the component area CA may have various shapes, such as a circular shape, an elliptical shape, a polygonal shape such as a quadrangle, a star shape, or a diamond shape. In addition, FIG. 1 shows that the component area CA is arranged at an upper center of the main display area MDA (in a +y direction) having an approximately quadrangular shape when viewed in a direction approximately perpendicular to the top surface of the display apparatus 1, but the component area CA may be arranged on one side, for example, an upper right side or an upper left side, of the main display area MDA having a quadrangular shape.

The display apparatus 1 may provide an image by using a plurality of main sub-pixels Pm arranged in the main display area MDA and a plurality of auxiliary sub-pixels Pa arranged in the component area CA.

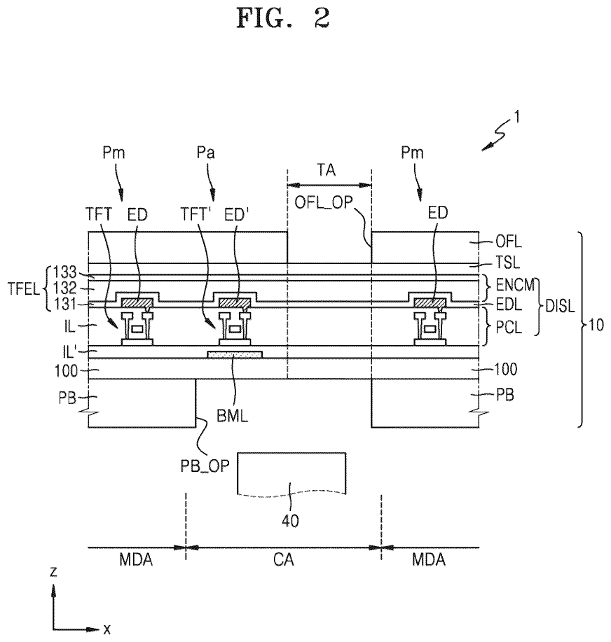

As described below with reference to FIG. 2, in the component area CA, a component 40, which is an electronic element, may be arranged under a display panel corresponding to the component area CA. The component 40 may be a camera that uses infrared or visible light, and may include an imaging element. Alternatively, the component 40 may be a solar cell, a flash, an illumination sensor, a proximity sensor, or an iris sensor. Alternatively, the component 40 may have a function of receiving sound. To minimize limitations on the function of the component 40, the component area CA may include a transmission area TA through which at least one of light and sound that is output from the component 40 or travels from the outside toward the component 40, may be transmitted. In the case of a display panel according to an embodiment and a display apparatus including the same, when light is allowed to pass through the component area CA, light transmittance may be about 10% or more, for example, 40% or more, 25% or more, 50% or more, 85% or more, or 90% or more.

The plurality of auxiliary sub-pixels Pa may be arranged in the component area CA. The plurality of auxiliary sub-pixels Pa may provide a certain image by emitting light. An image displayed in the component area CA is an auxiliary image and may have lower resolution than an image displayed in the main display area MDA. In other words, the component area CA includes the transmission area TA through which light and sound may pass, and when a sub-pixel is not arranged in the transmission area TA, the number of auxiliary sub-pixels Pa that may be arranged per unit area may be smaller than the number of main sub-pixels Pm arranged per unit area in the main display area MDA.

FIG. 2 is a cross-sectional view schematically showing a portion of a cross-section of the display apparatus 1 according to an embodiment.

Referring to FIG. 2, the display apparatus 1 may include a display panel 10 and the component 40 overlapping the display panel 10. A cover window (not shown) for protecting the display panel 10 may be further arranged above the display panel 10.

The display panel 10 includes the component area CA overlapping the component 40 and the main display area MDA where a main image is displayed. The display panel 10 may include: a substrate 100; a display layer DISL, a touch screen layer TSL, and an optical functional layer OFL, on the substrate 100; and a panel protection member PB arranged under the substrate 100.

The display layer DISL may include: a circuit layer PCL including a main thin-film transistor TFT and an auxiliary thin-film transistor TFT′; a display element layer EDL including a main light-emitting element ED and an auxiliary light-emitting element ED′, which are display elements; and a sealing member ENCM such as a thin-film encapsulation layer TFEL or a sealing substrate (not shown). An inorganic insulating layer IL may be arranged in the display layer DISL, and an insulating layer IL′ may be arranged between the substrate 100 and the display layer DISL.

The substrate 100 may include an insulating material such as glass, quartz, or polymer resin. The substrate 100 may be a rigid substrate or a flexible substrate that is bendable, foldable, or rollable.

In the main display area MDA of the display panel 10, the main thin-film transistor TFT and the main light-emitting element ED connected thereto may be arranged to implement a main sub-pixel Pm, and in the component area CA, the auxiliary thin-film transistor TFT′ and the auxiliary light-emitting element ED′ connected thereto may be arranged to implement an auxiliary sub-pixel Pa. An area where the auxiliary sub-pixel Pa is arranged in the component area CA may be referred to as an auxiliary display area ADA.

In addition, the transmission area TA where a display element is not arranged may be arranged in the component area CA. The transmission area TA may be an area through which light/signals emitted from the component 40 arranged to correspond to the component area CA, or light/signals incident on the component area CA, pass. The auxiliary display area ADA and the transmission area TA may be alternately arranged in the component area CA.

A lower metal layer BML may be arranged in the component area CA. The lower metal layer BML may be arranged to correspond to a bottom portion of the auxiliary thin-film transistor TFT′. For example, the lower metal layer BML may be arranged between the auxiliary thin-film transistor TFT′ and the substrate 100. The lower metal layer BML may block external light from reaching the auxiliary thin-film transistor TFT′. In some embodiments, a constant voltage or a signal is applied to the lower metal layer BML to prevent damage to a pixel circuit caused by electrostatic discharge.

The display element layer EDL may be covered with the thin-film encapsulation layer TFEL or the sealing substrate. In some embodiments, the thin-film encapsulation layer TFEL may include at least one inorganic encapsulation layer and at least one organic encapsulation layer, as shown in FIG. 2. In an embodiment, the thin-film encapsulation layer TFEL may include first and second inorganic encapsulation layers 131 and 133 and an organic encapsulation layer 132 arranged therebetween.

The first and second inorganic encapsulation layers 131 and 133 may include at least one inorganic insulating material among aluminum oxide, titanium oxide, tantalum oxide, hafnium oxide, zinc oxide, silicon oxide, silicon nitride, and silicon oxynitride. The organic encapsulation layer 132 may include a polymer-based material. The polymer-based material may include acrylic resin, epoxy-based resin, polyimide, and polyethylene.

When the display element layer EDL is sealed with the sealing substrate (not shown), the sealing substrate may be arranged to face the substrate 100 with the display element layer EDL therebetween. There may be a gap between the sealing substrate and the display element layer EDL. The sealing substrate may include glass. A sealant including frit may be arranged between the substrate 100 and the sealing substrate, and the sealant may be arranged in the peripheral area DPA. The sealant arranged in the peripheral area DPA may surround the display area DA and prevent moisture from penetrating through a side surface of the display panel 10.

The touch screen layer TSL may obtain coordinate information of an external input, for example, a touch event. The touch screen layer TSL may include a touch electrode and touch wirings connected to the touch electrode. The touch screen layer TSL may detect an external input by using self-capacitance or mutual capacitance.

The touch screen layer TSL may be formed on the thin-film encapsulation layer TFEL. Alternatively, the touch screen layer TSL may be formed separately on a touch substrate and then bonded onto the thin-film encapsulation layer TFEL via an adhesive layer such as an optically clear adhesive (OCA). In an embodiment, the touch screen layer TSL may be formed directly on the thin-film encapsulation layer TFEL, and in this case, the adhesive layer may not be arranged between the touch screen layer TSL and the thin-film encapsulation layer TFEL.

The optical functional layer OFL may include an anti-reflection layer. The anti-reflection layer may reduce reflectance of light (external light) incident on the display apparatus 1 from the outside.

In some embodiments, the optical functional layer OFL may be a polarizing film. The optical functional layer OFL may include an opening OFL_OP corresponding to the transmission area TA. Accordingly, light transmittance of the transmission area TA may be significantly improved. The opening OFL_OP may be filled with a transparent material such as an optically clear resin (OCR).

In some embodiments, the optical functional layer OFL may be provided as a filter plate including a black matrix and color filters.

The cover window (not shown) may be arranged above the display panel 10 to protect the display panel 10. The optical functional layer OFL may be attached to the cover window with an OCA, or may be attached to the touch screen layer TSL with an OCA.

The panel protection member PB may be attached to a bottom portion of the substrate 100 to support and protect the substrate 100. The panel protection member PB may include an opening PB_OP corresponding to the component area CA. By including the opening PB_OP in the panel protection member PB, light transmittance of the component area CA may be improved. The panel protection member PB may include polyethylene terephthalate (PET) or polyimide (PI).

The area of the component area CA may be larger than the area where the component 40 is arranged. Accordingly, the area of the opening PB_OP provided in the panel protection member PB may not be the same as the area of the component area CA.

In addition, a plurality of components 40 may be arranged in the component area CA. The plurality of components 40 may have different functions from each other. For example, the plurality of components 40 may include at least two of a camera (imaging element), a solar cell, a flash, a proximity sensor, an illumination sensor, and an iris sensor.

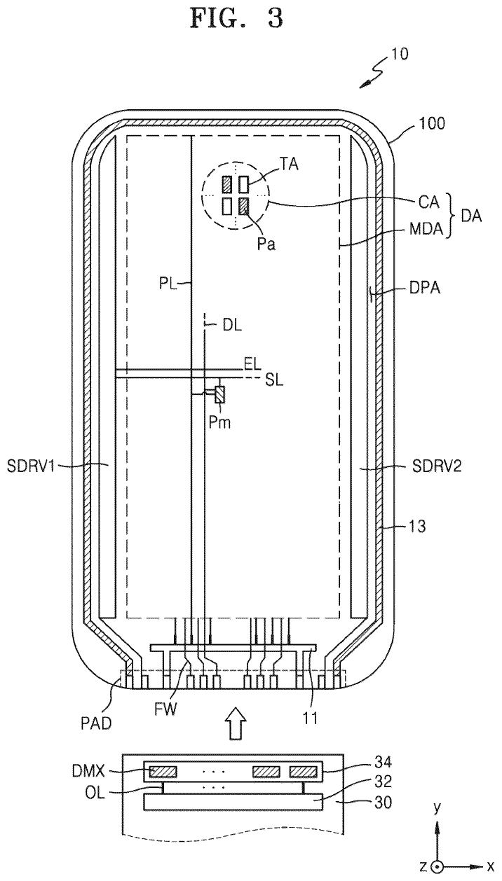

FIG. 3 is a plan view schematically illustrating the display panel 10 according to an embodiment.

Referring to FIG. 3, various components of the display panel 10 are arranged on the substrate 100. The substrate 100 includes the display area DA and the peripheral area DPA surrounding the display area DA. The display area DA includes: the main display area MDA where a main image is displayed; and the component area CA that has the transmission area TA and where an auxiliary image is displayed. As described above, the main display area MDA may be a first display area, and the component area CA may be a second display area.

The auxiliary image may form a single complete image together with the main image, or may be an image independent from the main image.

A plurality of main sub-pixels Pm may be arranged in the main display area MDA. Each of the main sub-pixels Pm may be implemented as a display element such as an organic light-emitting diode OLED. Each main sub-pixel Pm may emit, for example, red light, green light, blue light, or white light. The main display area MDA may be covered with a sealing member and protected from external air or moisture.

The component area CA may be arranged on one side of the main display area MDA as described above, or may be arranged on an inner side of the display area DA and surrounded by the main display area MDA. A plurality of auxiliary sub-pixels Pa may be arranged in the component area CA. Each of the auxiliary sub-pixels Pa may be implemented by a display element such as the organic light-emitting diode OLED. Each auxiliary sub-pixel Pa may emit, for example, red light, green light, blue light, or white light. The component area CA may be covered with a sealing member and protected from external air or moisture.

In addition, the component area CA may have the transmission area TA. The transmission area TA may be arranged to surround the plurality of auxiliary sub-pixels Pa. Alternatively, the transmission area TA may be arranged to have a grid form with the plurality of auxiliary sub-pixels Pa.

Because the component area CA has the transmission area TA, the resolution of the component area CA may be lower than the resolution of the main display area MDA. For example, the resolution of the component area CA may be about ½, ⅜, ⅓, ¼, 2/9, ⅛, 1/9, or 1/16 of the resolution of the main display area MDA. For example, the resolution of the main display area MDA may be greater than or equal to about 400 ppi, and the resolution of the component area CA may be about 200 ppi or about 100 ppi.

Each of pixel circuits configured to drive the sub-pixels Pm and Pa may be electrically connected to peripheral circuits arranged in the peripheral area DPA. A first scan driving circuit SDRV1, a second scan driving circuit SDRV2, a terminal unit PAD, a driving voltage supply line 11, and a common voltage supply line 13 may be arranged in the peripheral area DPA.

The first scan driving circuit SDRV1 may apply a scan signal to each of the pixel circuits configured to drive the sub-pixels Pm and Pa via a second scan line SL. The first scan driving circuit SDRV1 may be configured to apply an emission control signal to each pixel circuit via an emission control line EL. The second scan driving circuit SDRV2 may be arranged opposite to the first scan driving circuit SDRV1 with respect to the main display area MDA, and may be approximately parallel to the first scan driving circuit SDRV1. Some of pixel circuits of the main sub-pixels Pm in the main display area MDA may be electrically connected to the first scan driving circuit SDRV1, and the others may be electrically connected to the second scan driving circuit SDRV2. Some of pixel circuits of the auxiliary sub-pixels Pa in the component area CA may be electrically connected to the first scan driving circuit SDRV1, and the others may be electrically connected to the second scan driving circuit SDRV2. The second scan driving circuit SDRV2 may be omitted.

The terminal unit PAD may be arranged on one side of the substrate 100. The terminal unit PAD may be exposed without being covered by an insulating layer and may be connected to a display circuit board 30. A display driver 32 may be arranged on the display circuit board 30.

The display driver 32 may generate data signals. The data signals generated by the display driver 32 may be transmitted to a data distribution unit 34 via output lines OL. The data distribution unit 34 may include demultiplexers DMX including a plurality of switches. The data distribution unit 34 may electrically connect some of data lines (for example, a first group) to the display driver 32 during a first period, and may electrically connect some of the data lines (for example, a second group) to the display driver 32 during a second period. In other words, the data signals may be time-divisionally distributed by the data distribution unit 34.

The data signals distributed by the data distribution unit 34 may be transmitted to the pixel circuits of the sub-pixels Pm and Pa via a fan-out wiring FW and a data line DL connected to the fan-out wiring FW.

The display driver 32 may supply a driving voltage ELVDD to the driving voltage supply line 11, and may supply a common voltage ELVSS to the common voltage supply line 13. The driving voltage ELVDD may be applied to the pixel circuits of the sub-pixels Pm and Pa via a driving voltage line PL connected to the driving voltage supply line 11, and the common voltage ELVSS may be applied to an opposite electrode of the display element via the common voltage supply line 13.

In the drawing, the display driver 32 and the data distribution unit 34 are arranged on the display circuit board 30, but the disclosure is not limited thereto. The display driver 32 and the data distribution unit 34 may be arranged in the peripheral area DPA of the substrate 100.

The driving voltage supply line 11 may extend in an x direction, at a lower side of the main display area MDA. The common voltage supply line 13 has a loop shape with one side open and may partially surround the main display area MDA.

FIG. 3 shows one component area CA, but a plurality of component areas CA may be provided. In this case, the plurality of component areas CA may be spaced apart from each other, wherein a first camera may be arranged to correspond to one component area CA, and a second camera may be arranged to correspond to another component area CA. Alternatively, a camera may be arranged to correspond to one component area CA, and an infrared sensor may be arranged to correspond to another component area CA. The plurality of component areas CA may have different shapes and sizes from each other.

The component area CA may have a polygonal shape. For example, the component area CA may have an octagonal shape. The component area CA may have various polygonal shapes, such as a quadrangular shape, or a hexagonal shape. The component area CA may be surrounded by the main display area MDA.

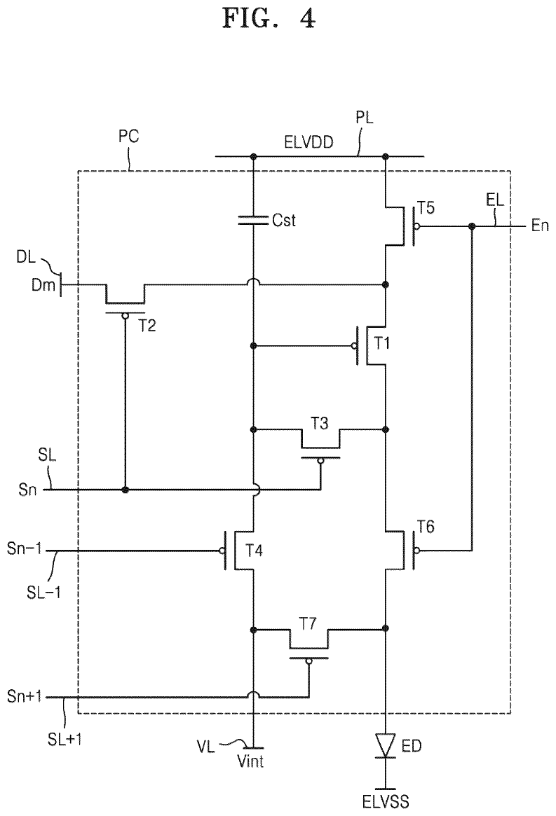

FIG. 4 is an equivalent circuit diagram of a pixel circuit configured to drive a sub-pixel, according to an embodiment.

Referring to FIG. 4, a pixel circuit PC may include a driving thin-film transistor T1, a switching thin-film transistor T2, a compensation thin-film transistor T3, a first initialization thin-film transistor T4, an operation control thin-film transistor T5, an emission control thin-film transistor T6, a second initialization thin-film transistor T7, and a storage capacitor Cst.

FIG. 4 shows that each of pixel circuits PC includes the second scan line SL, a first scan line SL−1, a third scan line SL+1, the emission control line EL, the data line DL, an initialization voltage line VL, and the driving voltage line PL. In another embodiment, at least one of the second scan line SL, the first scan line SL−1, the third scan line SL+1, the emission control line EL, and the data line DL, and/or the initialization voltage line VL may be shared by neighboring pixel circuits.

A drain electrode of the driving thin-film transistor T1 may be electrically connected to a light-emitting element ED via the emission control thin-film transistor T6. The driving thin-film transistor T1 may be configured to receive a data signal Dm according to a switching operation of the switching thin-film transistor T2 and supply a driving current to the light-emitting element ED.

A gate electrode of the switching thin-film transistor T2 may be connected to the second scan line SL, and a source electrode of the switching thin-film transistor T2 may be connected to the data line DL. A drain electrode of the switching thin-film transistor T2 may be connected to a source electrode of the driving thin-film transistor T1 and may also be connected to the driving voltage line PL via the operation control thin-film transistor T5.

The switching thin-film transistor T2 may be configured to perform a switching operation of being turned on according to a scan signal Sn received via the second scan line SL and transmitting, to the source electrode of the driving thin-film transistor T1, the data signal Dm transmitted via the data line DL.

A gate electrode of the compensation thin-film transistor T3 may be connected to the second scan line SL. A source electrode of the compensation thin-film transistor T3 may be connected to the drain electrode of the driving thin-film transistor T1 and may also be connected to a pixel electrode of the light-emitting element ED via the emission control thin-film transistor T6. A drain electrode of the compensation thin-film transistor T3 may be connected to any one electrode of the storage capacitor Cst, a source electrode of the first initialization thin-film transistor T4, and a gate electrode of the driving thin-film transistor T1. The compensation thin-film transistor T3 may be turned on according to the scan signal Sn received via the second scan line SL and may thus be configured to connect the gate electrode and the drain electrode of the driving thin-film transistor T1 to each other, thereby making the driving thin-film transistor T1 a diode-connected transistor.

A gate electrode of the first initialization thin-film transistor T4 may be connected to the first scan line SL−1. A drain electrode of the first initialization thin-film transistor T4 may be connected to the initialization voltage line VL. The source electrode of the first initialization thin-film transistor T4 may be connected to any one electrode of the storage capacitor Cst, the drain electrode of the compensation thin-film transistor T3, and the gate electrode of the driving thin-film transistor T1. The first initialization thin-film transistor T4 may be turned on according to the previous scan signal Sn−1 received via the first scan line SL−1 and may thus be configured to transmit an initialization voltage Vint to the gate electrode of the driving thin-film transistor T1 to initialize a voltage of the gate electrode of the driving thin-film transistor T1.

A gate electrode of the operation control thin-film transistor T5 may be connected to the emission control line EL. A source electrode of the operation control thin-film transistor T5 may be connected to the driving voltage line PL. A drain electrode of the operation control thin-film transistor T5 may be connected to the source electrode of the driving thin-film transistor T1 and the drain electrode of the switching thin-film transistor T2.

A gate electrode of the emission control thin-film transistor T6 may be connected to the emission control line EL. A source electrode of the emission control thin-film transistor T6 may be connected to the drain electrode of the driving thin-film transistor T1 and the source electrode of the compensation thin-film transistor T3. A drain electrode of the emission control thin-film transistor T6 may be electrically connected to the pixel electrode of the light-emitting element ED. The operation control thin-film transistor T5 and the emission control thin-film transistor T6 are simultaneously turned on according to an emission control signal En received via the emission control line EL, such that the driving voltage ELVDD is transmitted to the light-emitting element ED, and a driving current flows through the light-emitting element ED.

A gate electrode of the second initialization thin-film transistor T7 may be connected to the third scan line SL+1. A source electrode of the second initialization thin-film transistor T7 may be connected to the pixel electrode of the light-emitting element ED. A drain electrode of the second initialization thin-film transistor T7 may be connected to the initialization voltage line VL. The second initialization thin-film transistor T7 may be turned on according to a subsequent scan signal Sn+1 received via the third scan line SL+1 and may thus initialize the pixel electrode of the light-emitting element ED.

FIG. 4 shows that the first initialization thin-film transistor T4 and the second initialization thin-film transistor T7 are respectively connected to the first scan line SL−1 and the third scan line SL+1, but the disclosure is not limited thereto. In another embodiment, both the first initialization thin-film transistor T4 and the second initialization thin-film transistor T7 may be connected to the first scan line SL−1 and may be driven according to a previous scan signal Sn−1.

The other electrode of the storage capacitor Cst may be connected to the driving voltage line PL. Any one electrode of the storage capacitor Cst may be connected to the gate electrode of the driving thin-film transistor T1, the drain electrode of the compensation thin-film transistor T3, and the source electrode of the first initialization thin-film transistor T4.

An opposite electrode (for example, a cathode) of the light-emitting element ED receives the common voltage ELVSS. The light-emitting element ED receives a driving current from the driving thin-film transistor T1 and emits light.

The pixel circuit PC is not limited to the number of thin-film transistors, the number of storage capacitors, and a circuit design, described with reference to FIG. 4, and the numbers and the circuit design may be variously modified. The pixel circuits PC configured to drive the main sub-pixel Pm and the auxiliary sub-pixel Pa may be provided identically or differently. Herein, the pixel circuit PC configured to drive the main sub-pixel Pm may be referred to as a first pixel circuit, and the pixel circuit PC configured to drive the auxiliary sub-pixel Pa may be referred to as a second pixel circuit.

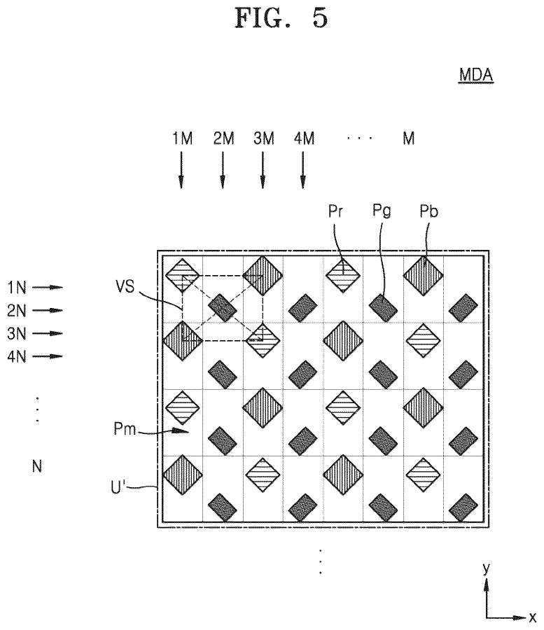

FIG. 5 is a layout diagram schematically showing a pixel arrangement structure in a main display area, according to an embodiment.

A plurality of main sub-pixels Pm may be arranged in the main display area MDA. Herein, a sub-pixel refers to an emission area, which is a minimum unit that implements an image. In addition, when an organic light-emitting diode is used as the display element, the emission area may be defined by an opening in a pixel-defining film. This will be described later.

As in FIG. 5, the main sub-pixels Pm arranged in the main display area MDA may be arranged according to a Pentile structure. A red sub-pixel Pr, a green sub-pixel Pg, and a blue sub-pixel Pb may respectively emit red light, green light, and blue light.

A plurality of red sub-pixels Pr and a plurality of blue sub-pixels Pb are alternately arranged in a first row 1N, a plurality of green sub-pixels Pg are spaced apart from each other at certain intervals in an adjacent second row 2N, the plurality of blue sub-pixels Pb and the plurality of red sub-pixels Pr are alternately arranged in an adjacent third row 3N, and the plurality of green sub-pixels Pg are spaced apart from each other at certain intervals in an adjacent fourth row 4N, and this pixel arrangement is repeated up to an N^{th} row. In this case, the blue sub-pixel Pb and the red sub-pixel Pr may be larger than the green sub-pixel Pg.

The plurality of red sub-pixels Pr and the plurality of blue sub-pixels Pb are arranged in the odd-numbered rows (first row 1N, third row 3N, etc.) in an alternating manner. The plurality of green sub-pixels Pg arranged in the even-numbered rows (second row 2N, fourth row 4N, etc.) in an alternating orientation. Also, the plurality of red sub-pixels Pr and the plurality of blue sub-pixels Pb are alternately arranged in odd-numbered columns (a first column 1M, third column 3M, 5^{th} column 5M, etc.). The plurality of green sub-pixels Pg are spaced apart from each other at certain intervals in the even-=numbered columns (second column 2M, 4^{th} column 4M, etc.). This pixel arrangement is repeated up to an M^{th} column.

FIG. 5 depicts a virtual quadrangle VS. This pixel arrangement structure may be described as follows: the red sub-pixels Pr are respectively arranged at two vertices that are diagonal with respect to each other, a green sub-pixel Pg is positioned at a center point of the virtual quadrangle VS, and the blue sub-pixels Pb are respectively arranged at the remaining vertices that are diagonal with respect to each other. In this case, the virtual quadrangle VS may be modified into various shapes, such as a rectangle, a rhombus, or a square.

This pixel arrangement structure is referred to as a Pentile™ matrix structure or a Pentile structure, and by applying a rendering driving technique that expresses colors through sharing of adjacent pixels, high resolution may be implemented with a small number of pixels.

FIG. 5 shows that the plurality of main sub-pixels Pm are arranged according to a Pentile matrix structure, but the disclosure is not limited thereto. For example, the plurality of main sub-pixels Pm may be arranged in various shapes, such as a stripe structure, a mosaic arrangement structure, or a delta arrangement structure.

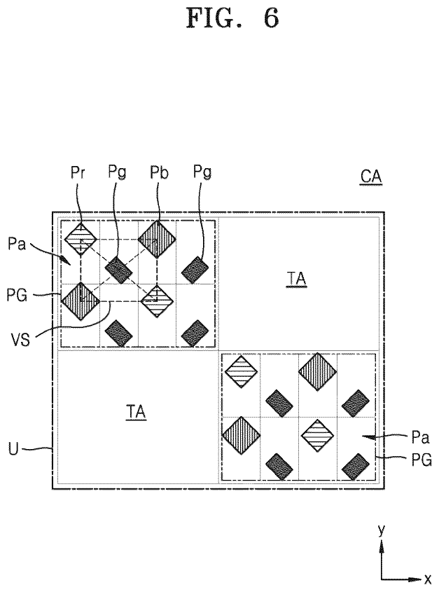

FIG. 6 is a layout diagram schematically showing a pixel arrangement structure in the component area CA, according to an embodiment.

Referring to FIG. 6, a plurality of auxiliary sub-pixels Pa may be arranged in the component area CA. Each of the auxiliary sub-pixels Pa may emit any one of red light, green light, blue light, and white light.

The component area CA may have: a pixel group PG including at least one auxiliary sub-pixel Pa; and the transmission area TA. The pixel group PG and the transmission area TA may be alternately arranged in the x direction and a y direction, and may be arranged in a checkerboard pattern. In this case, the component area CA may have a plurality of pixel groups PG and a plurality of transmission areas TA.

The pixel group PG may be defined as a sub-pixel array in which the plurality of auxiliary sub-pixels Pa are grouped together into a preset unit. For example, as depicted in FIG. 6, one pixel group PG may include eight auxiliary sub-pixels Pa arranged according to a Pentile structure. In other words, one pixel group PG may include two red sub-pixels Pr, four green sub-pixels Pg, and two blue sub-pixels Pb.

In the component area CA, a basic unit U in which a certain number of pixel groups PG and a certain number of transmission areas TA are grouped together may be repeatedly arranged in the x direction and the y direction. In FIG. 6, the basic unit U may have a quadrangular shape in which two pixel groups PG and two transmission areas TA arranged around the two pixel groups PG are grouped together. The basic unit U is a portion obtained by dividing a structure of repeating portions and does not imply structural discontinuity.

Although not explicitly depicted, a corresponding unit U′ having the same area as the basic unit U may be provided in the main display area MDA. In this case, the number of main sub-pixels Pm included in the corresponding unit U′ in the main display area MDA may be greater than the number of auxiliary sub-pixels Pa included in the basic unit U in the component area CA. In other words, the basic unit U may include 16 auxiliary sub-pixels Pa, and the corresponding unit U′ may include 32 main sub-pixels Pm, such that the number of auxiliary sub-pixels Pa and the number of main sub-pixels Pm, arranged per equal area, may be provided at a ratio of 1:2.

As in FIG. 6, a pixel arrangement structure of the component area CA, in which an arrangement structure of the auxiliary sub-pixels Pa is a Pentile structure and which has a resolution that is ½ that of the main display area MDA, is referred to as a ½ Pentile structure. The number or arrangement of auxiliary sub-pixels Pa included in the pixel group PG may be variably designed according to the resolution of the component area CA.

FIG. 6 shows that the plurality of auxiliary sub-pixels Pa are arranged according to a Pentile matrix structure, but the disclosure is not limited thereto. For example, the plurality of auxiliary sub-pixels Pa may be arranged in various configurations, such as a stripe configuration, a mosaic arrangement, or a delta arrangement.

FIG. 6 shows the size of the auxiliary sub-pixel Pa as having the same size as the main sub-pixel Pm in FIG. 5, but the disclosure is not limited thereto. The size of the auxiliary sub-pixel Pa may be greater than the size of the main sub-pixel Pm that produces the same color. For example, the size of the blue sub-pixel Pb of the auxiliary sub-pixel Pa may be greater than the size of the blue sub-pixel Pb of the main sub-pixel Pm. The size difference may be designed in consideration of differences in luminance and/or resolution between the component area CA and the main display area MDA.

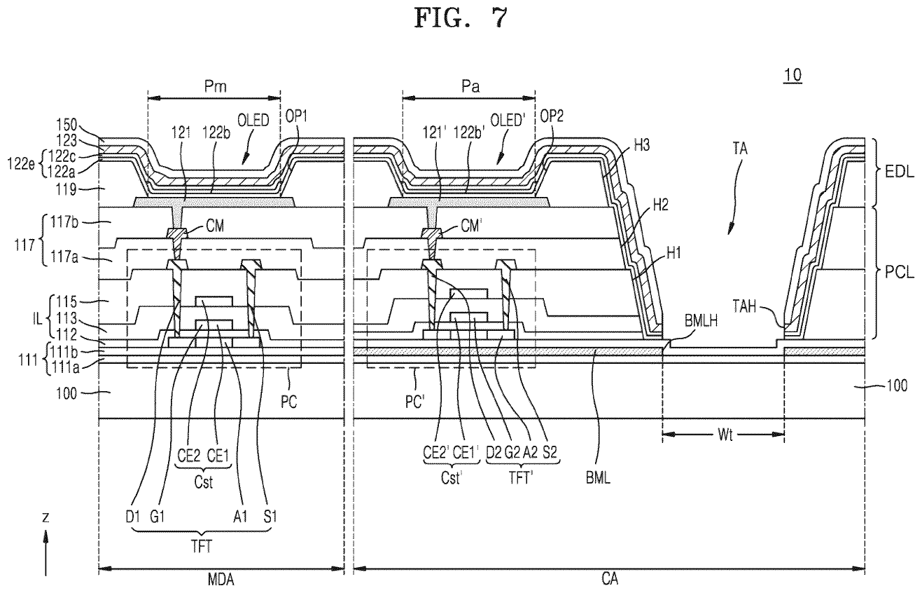

FIG. 7 is a schematic cross-sectional view illustrating a portion of the display panel 10 according to an embodiment, including the main display area MDA and the component area CA.

Referring to FIG. 7, the display panel 10 includes the main display area MDA and the component area CA. The main sub-pixel Pm is arranged in the main display area MDA, and the component area CA includes the auxiliary sub-pixel Pa and the transmission area TA. A first pixel circuit PC including the main thin-film transistor TFT and a main storage capacitor Cst and a main organic light-emitting diode OLED as a display element connected to the first pixel circuit PC may be arranged in the main display area MDA. A second pixel circuit PC′ including the auxiliary thin-film transistor TFT′ and an auxiliary storage capacitor Cst′ and an auxiliary organic light-emitting diode OLED′ as a display element connected to the second pixel circuit PC′ may be arranged in the component area CA.

In the present embodiment, an organic light-emitting diode is used as a display element, but in another embodiment, an inorganic light-emitting element or a quantum dot light-emitting element may be used as a display element.

Hereinafter, a structure in which components included in the display panel 10 are stacked is described. The display panel 10 may be provided by stacking the substrate 100, a buffer layer 111, the circuit layer PCL, the display element layer EDL, the sealing member ENCM, and the optical functional layer OFL.

As described above, the substrate 100 may include an insulating material such as glass, quartz, or polymer resin. The substrate 100 may be a rigid substrate or a flexible substrate that is bendable, foldable, or rollable.

The buffer layer 111 may be arranged on the substrate 100 to reduce or block penetration of foreign substances, moisture, or external air from the bottom portion of the substrate 100 and provide a flat surface on the substrate 100. The buffer layer 111 may include an inorganic material such as an oxide or a nitride, an organic material, or an organic-inorganic composite material, and may have a single-layered or multilayer structure of an inorganic material and an organic material. A barrier layer (not shown) that blocks penetration of external air may be further included between the substrate 100 and the buffer layer 111. In some embodiments, the buffer layer 111 may include silicon oxide (SiO₂) or silicon nitride (SiNₓ). The buffer layer 111 may be provided such that a first buffer layer 111a and a second buffer layer 111b are stacked.

In the component area CA, the lower metal layer BML may be arranged between the first buffer layer 111a and the second buffer layer 111b. In another embodiment, the lower metal layer BML may be arranged between the substrate 100 and the first buffer layer 111a. The lower metal layer BML may be arranged under the second pixel circuit PC′ and may prevent degradation of characteristics of the auxiliary thin-film transistor TFT′ caused by light emitted from a component or the like. In addition, the lower metal layer BML may prevent light emitted from or directed toward the component or the like from diffracting via a narrow gap between wirings connected to the second pixel circuit PC′. The lower metal layer BML is absent in the transmission area TA.

A bias voltage may be applied to the lower metal layer BML. By receiving the bias voltage, the lower metal layer BML may significantly reduce the probability of electrostatic discharge occurrence. The lower metal layer BML may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu). The lower metal layer BML may be provided as a single layer or multilayer including the above-described material.

The circuit layer PCL may be arranged on the buffer layer 111, and may include the pixel circuits PC and PC′, a first gate insulating layer 112, a second gate insulating layer 113, an interlayer insulating layer 115, and a planarization layer 117. The first pixel circuit PC may include the main thin-film transistor TFT and the main storage capacitor Cst, and the second pixel circuit PC′ may include the auxiliary thin-film transistor TFT′ and the auxiliary storage capacitor Cst′.

The main thin-film transistor TFT and the auxiliary thin-film transistor TFT′ may be arranged above the buffer layer 111. The main thin-film transistor TFT includes a first semiconductor layer A1, a first gate electrode G1, a first source electrode S1, and a first drain electrode D1, and the auxiliary thin-film transistor TFT′ includes a second semiconductor layer A2, a second gate electrode G2, a second source electrode S2, and a second drain electrode D2. The main thin-film transistor TFT may be connected to the main organic light-emitting diode OLED and may thus be configured to drive the main organic light-emitting diode OLED. The auxiliary thin-film transistor TFT′ may be connected to the auxiliary organic light-emitting diode OLED′ and may thus be configured to drive the auxiliary organic light-emitting diode OLED′.

The first semiconductor layer A1 and the second semiconductor layer A2 may be arranged on the buffer layer 111 and may include polysilicon. In another embodiment, the first semiconductor layer A1 and the second semiconductor layer A2 may include amorphous silicon. In another embodiment, the first semiconductor layer A1 and the second semiconductor layer A2 may include an oxide of at least one material selected from a group including indium (In), gallium (Ga), tin (Sn), zirconium (Zr), vanadium (V), hafnium (Hf), cadmium (Cd), germanium (Ge), chromium (Cr), titanium (Ti), and zinc (Zn). The first semiconductor layer A1 and the second semiconductor layer A2 may include a channel area, a source area, and a drain area, wherein the source area and the drain area are doped with impurities.

The second semiconductor layer A2 may overlap the lower metal layer BML with the second buffer layer 111b therebetween. In an embodiment, the width of the second semiconductor layer A2 may be smaller than the width of the lower metal layer BML, and thus, when viewed in a direction perpendicular to the substrate 100, the second semiconductor layer A2 may entirely overlap the lower metal layer BML.

The first gate insulating layer 112 may be provided to cover the first semiconductor layer A1 and the second semiconductor layer A2. The first gate insulating layer 112 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂). The first gate insulating layer 112 may be formed as a single layer or multilayer including the above-described inorganic insulating material.

The first gate electrode G1 and the second gate electrode G2 are arranged above the first gate insulating layer 112 to respectively overlap the first semiconductor layer A1 and the second semiconductor layer A2. The first gate electrode G1 and the second gate electrode G2 may include molybdenum (Mo), aluminum (Al), copper (Cu), or titanium (Ti) and may each be formed as a single layer or a multilayer. For example, the first gate electrode G1 and the second gate electrode G2 may each be a single layer of Mo.

The second gate insulating layer 113 may be provided to cover the first gate electrode G1 and the second gate electrode G2. The second gate insulating layer 113 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂). The second gate insulating layer 113 may be formed as a single layer or multilayer including the above-described inorganic insulating material.

A first upper electrode CE2 of the main storage capacitor Cst and a second upper electrode CE2′ of the auxiliary storage capacitor Cst′ may be arranged above the second gate insulating layer 113.

The first upper electrode CE2 may overlap the first gate electrode G1 arranged under the first upper electrode CE2, in the main display area MDA. The first gate electrode G1 and the first upper electrode CE2, which overlap each other with the second gate insulating layer 113 therebetween, may form the main storage capacitor Cst. The first gate electrode G1 may be a first lower electrode CE1 of the main storage capacitor Cst.

The second upper electrode CE2′ may overlap the second gate electrode G2 arranged under the second upper electrode CE2′, in the component area CA. The second gate electrode G2 and the second upper electrode CE2′, which overlap each other with the second gate insulating layer 113 therebetween, may form the auxiliary storage capacitor Cst′. The first gate electrode G1 may be a second lower electrode CE1′ of the auxiliary storage capacitor Cst′.

The first upper electrode CE2 and the second upper electrode CE2′ may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may each be formed as a single layer or multilayer including the above-described material.

The interlayer insulating layer 115 may be formed to cover the first upper electrode CE2 and the second upper electrode CE2′. The interlayer insulating layer 115 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂). The interlayer insulating layer 115 may be formed as a single layer or multilayer including the above-described inorganic insulating material.

When the first gate insulating layer 112, the second gate insulating layer 113, and the interlayer insulating layer 115 are collectively referred to as an inorganic insulating layer IL, the inorganic insulating layer IL may have a first hole H1 corresponding to the transmission area TA. The first hole H1 may expose a portion of a top surface of the buffer layer 111 or the substrate 100. The first hole H1 may be formed by overlapping an opening in the first gate insulating layer 112, an opening in the second gate insulating layer 113, and an opening in the interlayer insulating layer 115 with each other, wherein these three openings are formed to correspond to the transmission area TA. These openings may be formed individually via separate processes or simultaneously via a single process. When these openings are formed via separate processes, an inner surface of the first hole H1 may be uneven and may have steps.

In contrast, the inorganic insulating layer IL may have a groove other than the first hole H1 exposing the buffer layer 111. Alternatively, the inorganic insulating layer IL may not have the first hole H1 or a groove, each corresponding to the transmission area TA. The inorganic insulating layer IL generally includes an inorganic insulating material with excellent light transmittance, and thus, even without having a hole or groove corresponding to the transmission area TA, the inorganic insulating layer IL may have a sufficient transmittance, thereby allowing the component 40 (see FIG. 2) to transmit/receive a sufficient amount of light.

First and second source electrodes S1 and S2 and first and second drain electrodes D1 and D2 may be arranged on the interlayer insulating layer 115. The source electrodes S1 and S2 and the drain electrodes D1 and D2 may include a conductive material including molybdenum (Mo), aluminum (Al), copper (Cu), or titanium (Ti), and may be formed as a multilayer or single layer including the above material. For example, the source electrodes S1 and S2 and the drain electrodes D1 and D2 may each have a multilayer structure of Ti/Al/Ti.

The planarization layer 117 may be arranged to cover the source electrodes S1 and S2 and the drain electrodes D1 and D2. The planarization layer 117 may have a flat top surface such that a first pixel electrode 121 and a second pixel electrode 121′, which are arranged above the planarization layer 117, may be formed flat.

The planarization layer 117 may include an organic material or an inorganic material and may have a single-layered structure or a multilayer structure. The planarization layer 117 may include a first planarization layer 117a and a second planarization layer 117b. Accordingly, a conductive pattern such as a wiring may be formed between the first planarization layer 117a and the second planarization layer 117b, which may be advantageous for high integration.

The planarization layer 117 may include a general-purpose polymer such as benzocyclobutene (BCB), polyimide, hexamethyldisiloxane (HMDSO), polymethylmethacrylate (PMMA), or polystyrene (PS), a polymer derivative having a phenol-based group, an acrylic polymer, an imide-based polymer, an aryl ether-based polymer, an amide-based polymer, a fluorine-based polymer, a p-xylene-based polymer, or a vinyl alcohol-based polymer. In addition, the planarization layer 117 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂). When forming the planarization layer 117, after a layer is formed, in order to provide a flat top surface, chemical mechanical polishing may be performed on a top surface of the layer.

The first planarization layer 117a may be arranged to cover the pixel circuits PC and PC′. The second planarization layer 117b may be arranged on the first planarization layer 117a, and may have a flat top surface such that the pixel electrodes 121 and 121′ may be formed flat.

The organic light-emitting diodes OLED and OLED′ are arranged on the second planarization layer 117b. The pixel electrodes 121 and 121′ of the organic light-emitting diodes OLED and OLED′ may be connected to the pixel circuits PC and PC′ via connection electrodes CM and CM′ arranged on the planarization layer 117.

The connection electrodes CM and CM′ may be arranged between the first planarization layer 117a and the second planarization layer 117b. The connection electrodes CM and CM′ may include a conductive material including molybdenum (Mo), aluminum (Al), copper (Cu), or titanium (Ti), and may be formed as a multilayer or single layer including the above material. For example, the connection electrodes CM and CM′ may each have a multilayer structure of Ti/Al/Ti.

The planarization layer 117 may have a second hole H2 corresponding to the transmission area TA. The second hole H2 may overlap the first hole H1. FIG. 7 shows that the second hole H2 is formed larger than the first hole H1. In another embodiment, the planarization layer 117 may be provided to cover an edge of the first hole H1 in the inorganic insulating layer IL, and thus, the area of the second hole H2 may be formed smaller than the area of the first hole H1.

The planarization layer 117 may have a via hole exposing any one of the first source electrode S1 and the first drain electrode D1 of the main thin-film transistor TFT, and the first pixel electrode 121 may be in contact with the first source electrode S1 or the first drain electrode D1 via the via hole and may thus be electrically connected to the main thin-film transistor TFT. In addition, the planarization layer 117 may have a via hole exposing any one of the second source electrode S2 and the second drain electrode D2 of the auxiliary thin-film transistor TFT′, and the second pixel electrode 121′ may be in contact with the second source electrode S2 or the second drain electrode D2 via the via hole and may thus be electrically connected to the auxiliary thin-film transistor TFT′.

The first pixel electrode 121 and the second pixel electrode 121′ may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). The first pixel electrode 121 and the second pixel electrode 121′ may include a reflective film including silver (Ag), magnesium (Mg), aluminum (Al), platinum (Pt), palladium (Pd), gold (Au), nickel (Ni), neodymium (Nd), iridium (Ir), chromium (Cr), or a compound thereof. For example, the first pixel electrode 121 and the second pixel electrode 121′ may have a structure in which films including ITO, IZO, ZnO, or In₂O₃ are formed above/under the above-described reflective film. In this case, the first pixel electrode 121 and the second pixel electrode 121′ may have a stacked structure of ITO/Ag/ITO.

A pixel-defining film 119 may cover an edge of each of the first pixel electrode 121 and the second pixel electrode 121′, on the planarization layer 117, and may include a first opening OP1 exposing a central portion of the first pixel electrode 121 and a second opening OP2 exposing a central portion of the second pixel electrode 121′. The shapes and sizes of emission areas of the organic light-emitting diodes OLED and OLED′, i.e., the sub-pixels Pm and Pa, are defined by the first opening OP1 and the second opening OP2.

The pixel-defining film 119 may prevent an arc or the like from occurring at the edges of the pixel electrodes 121 and 121′ by increasing a distance between the edges of the pixel electrodes 121 and 121′ and an opposite electrode 123 above the pixel electrodes 121 and 121′. The pixel-defining film 119 may include an organic insulating material such as polyimide, polyamide, acrylic resin, BCB, HMDSO, and phenolic resin, and may be formed by a method such as spin coating.

The pixel-defining film 119 may include a third hole H3 located in the transmission area TA. The third hole H3 may overlap the first hole H1 and the second hole H2. Light transmittance in the transmission area TA may be improved by the first hole H1, the second hole H2, and the third hole H3. In addition, FIG. 6 shows that the buffer layer 111 is continuously arranged to correspond to the transmission area TA, but the buffer layer 111 may include a hole located in the transmission area TA. Portions of the opposite electrode 123 described later may be arranged on inner surfaces of the first hole H1 to the third hole H3.

A first emission layer 122b and a second emission layer 122b′, which are formed to respectively correspond to the first pixel electrode 121 and the second pixel electrode 121′, are respectively arranged in the first opening OP1 and the second opening OP2 in the pixel-defining film 119. The first emission layer 122b and the second emission layer 122b′ may include a polymer material or a low-molecular-weight material, and may emit red light, green light, blue light, or white light.

An organic functional layer 122e may be arranged above and/or under the first emission layer 122b and the second emission layer 122b′. The organic functional layer 122e may include a first functional layer 122a and/or a second functional layer 122c. The first functional layer 122a or the second functional layer 122c may be omitted.

The first functional layer 122a may be arranged under the first emission layer 122b and the second emission layer 122b′. The first functional layer 122a may be formed as a single layer or multilayer including an organic material. The first functional layer 122a may be a hole transport layer having a single-layered structure. Alternatively, the first functional layer 122a may include a hole injection layer and a hole transport layer. The first functional layer 122a may be integrally formed to correspond to the organic light-emitting diodes OLED and OLED′ respectively included in the main display area MDA and the component area CA.

The second functional layer 122c may be arranged above the first emission layer 122b and the second emission layer 122b′. The second functional layer 122c may be formed as a single layer or multilayer including an organic material. The second functional layer 122c may include an electron transport layer and/or an electron injection layer. The second functional layer 122c may be integrally formed to correspond to the organic light-emitting diodes OLED and OLED′ respectively included in the main display area MDA and the component area CA.

The opposite electrode 123 may be arranged above the second functional layer 122c. The opposite electrode 123 may include a conductive material having a low work function. For example, the opposite electrode 123 may include a (semi-)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. Alternatively, the opposite electrode 123 may further include a layer including ITO, IZO, ZnO, or In₂O₃ on the (semi-)transparent layer including the above-described material. The opposite electrode 123 may be integrally formed to correspond to the organic light-emitting diodes OLED and OLED′ respectively included in the main display area MDA and the component area CA.

Layers from the first pixel electrode 121 to the opposite electrode 123, formed in the main display area MDA, may form the main organic light-emitting diode OLED. Layers from the second pixel electrode 121′ to the opposite electrode 123, formed in the component area CA, may form the auxiliary organic light-emitting diode OLED′.

An upper layer 150 including an organic material may be formed on the opposite electrode 123. The upper layer 150 may be provided to protect the opposite electrode 123 and simultaneously increase light extraction efficiency. The upper layer 150 may include an organic material having a higher refractive index than the opposite electrode 123. Alternatively, the upper layer 150 may be provided by stacking layers having different refractive indices from each other. For example, the upper layer 150 may be provided by stacking a high-refractive index layer/low-refractive index layer/high-refractive index layer. In this case, the refractive index of the high-refractive index layer may be 1.7 or more, and the refractive index of the low-refractive index layer may be 1.3 or less.

The upper layer 150 may further include LiF. Alternatively, the upper layer 150 may further include an inorganic insulating material such as silicon oxide (SiO₂) or silicon nitride (SiNₓ).

The first functional layer 122a, the second functional layer 122c, the opposite electrode 123, and the upper layer 150 may each include a transmission hole TAH corresponding to the transmission area TA. In other words, the first functional layer 122a, the second functional layer 122c, the opposite electrode 123, and the upper layer 150 may each have an opening corresponding to the transmission area TA. The areas of the openings may be substantially the same. For example, the area of an opening in the opposite electrode 123 may be substantially the same as the area of the transmission hole TAH.

When the transmission hole TAH corresponds to the transmission area TA, it may be understood that the transmission hole TAH overlaps the transmission area TA. In this case, the area of the transmission hole TAH may be smaller than the area of the first hole H1 formed in the inorganic insulating layer IL. To this end, FIG. 7 shows that a width Wt of the transmission hole TAH may be smaller than the width of the first hole H1. In this regard, the area of the transmission hole TAH may be defined as the area of an opening having the smallest area among openings of the transmission hole TAH, in plan view. The area of the first hole H1 may also be defined as the area of an opening having the smallest area among the first hole H1, the second hole H2, and the third hole H3.

Due to the transmission hole TAH, a portion of the opposite electrode 123 is absent in the transmission area TA, and accordingly, light transmittance in the transmission area TA may be significantly increased. The opposite electrode 123 including the transmission hole TAH may be formed by various methods. In an embodiment, a material for forming the opposite electrode 123 may be formed on an entire surface of the substrate 100, and a portion corresponding to the transmission area TA may be removed by laser lift-off, thereby forming the opposite electrode 123 having the transmission hole TAH. In another embodiment, the opposite electrode 123 having the transmission hole TAH may be formed via a metal self-patterning (MSP) process. In another embodiment, the opposite electrode 123 having the transmission hole TAH may be formed via a method of depositing the opposite electrode 123 by using a fine metal mask (FMM).

The lower metal layer BML in the component area CA may be provided to correspond to the entire component area CA. In this case, the lower metal layer BML may include a lower hole BMLH overlapping the transmission area TA. In some embodiments, the shape and size of the transmission area TA may be defined by the shape and size of the lower hole BMLH.

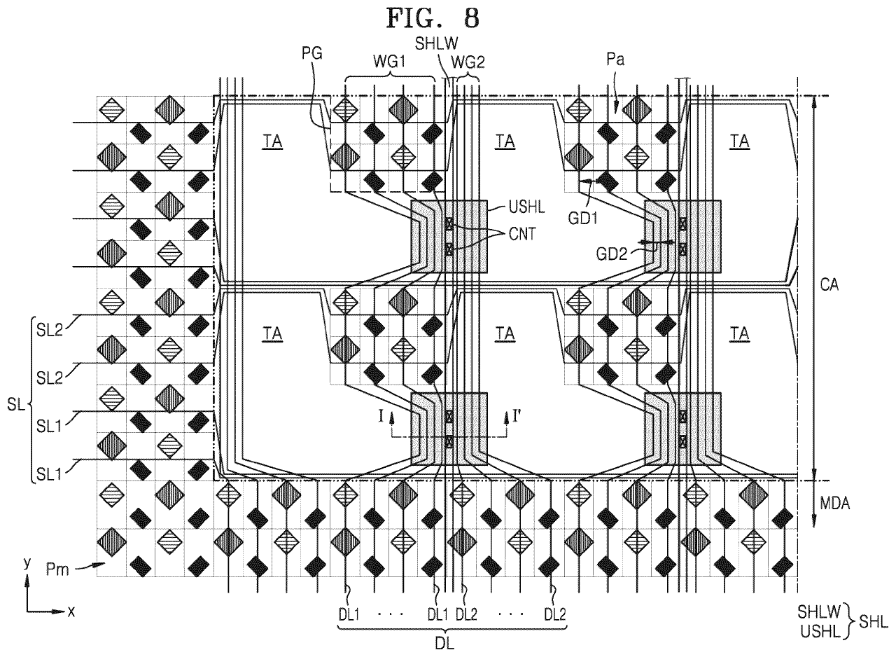

FIG. 8 is a plan view schematically showing an arrangement relationship of sub-pixels and wirings of a display panel according to an embodiment. Because this plan view shows only a portion of the display panel, additional sub-pixels are omitted. In addition, because this plan view shows only wirings necessary for explanation, additional wirings are omitted. This plan view shows the component area CA and a portion of the main display area MDA outside the component area CA.

Referring to FIG. 8, in the main display area MDA, the main sub-pixels Pm and first pixel circuits configured to drive the main sub-pixels Pm may be arranged, and in the component area CA, second pixel circuits configured to drive auxiliary sub-pixels Pa may be arranged to form the pixel group PG. The pixel groups PG may be arranged with the transmission area TA therebetween. The pixel groups PG and the transmission areas TA may be alternately arranged relative to each other.

Scan lines SL may extend in the x direction to transmit scan signals to the first pixel circuits of the main sub-pixels Pm and the second pixel circuits of the auxiliary sub-pixels Pa. Data lines DL may extend in the y direction to transmit data signals to the first pixel circuits of the main sub-pixels Pm and the second pixel circuits of the auxiliary sub-pixels Pa. The data lines DL may be arranged in a different layer from the scan lines SL.

The scan lines SL may include first scan lines SL1 and second scan lines SL2. The first scan lines SL1 may extend in the x direction to electrically connect the first pixel circuits of the main sub-pixels Pm arranged in the same row in the main display area MDA, and may be arranged across the transmission area TA in the component area CA while not being connected to the second pixel circuits of the auxiliary sub-pixels Pa. The second scan lines SL2 may extend in the x direction to electrically connect the first pixel circuits of the main sub-pixels Pm and the second pixel circuits of the auxiliary sub-pixels Pa to each other, which are arranged in the same row in the main display area MDA and the component area CA.

The data lines DL may include a first wiring group WG1 and a second wiring group WG2. The first wiring group WG1 may include first data lines DL1. The second wiring group WG2 may include second data lines DL2.

The first data lines DL1 may extend in the y direction to electrically connect the first pixel circuits of the main sub-pixels Pm and the second pixel circuits of the auxiliary sub-pixels Pa to each other, which are arranged in the same column in the main display area MDA and the component area CA.

The second data lines DL2 may extend approximately in the y direction to electrically connect the first pixel circuits of the main sub-pixels Pm arranged in the same column in the main display area MDA, and may extend to the peripheral area DPA across the transmission area TA in the component area CA.

The scan lines SL and the data lines DL, arranged in the component area CA, may be arranged to be biased to one side rather than being arranged at a central portion of the transmission area TA in order to increase light transmittance in the component area CA. To this end, the scan lines SL and the data lines DL, arranged in the component area CA, may be appropriately bent. Accordingly, a distance between the scan lines SL passing between the pixel groups PG that are spaced apart from each other may be less than a distance between the scan lines SL passing through sub-pixels in the pixel group PG. In addition, a distance GD1 between the data lines DL passing between the pixel groups PG that are spaced apart from each other may be less than a distance GD2 between the data lines DL passing through sub-pixels in the pixel group PG.

A shielding layer SHL may be at least partially arranged between the first wiring group WG1 and the second wiring group WG2. The shielding layer SHL may be provided by stacking a shielding wiring SHLW and an upper shielding layer USHL, which are arranged in different layers from each other and are connected to each other via a contact hole CNT.

The shielding wiring SHLW may be arranged, in a plan view, between the first wiring group WG1 and the second wiring group WG2 in the component area CA, and may extend in the y direction. The shielding wiring SHLW may extend not only to the component area CA but also to the main display area MDA. Alternatively, the shielding wiring SHLW may be arranged only in the component area CA.

The upper shielding layer USHL may be arranged above the shielding wiring SHLW while overlapping the shielding wiring SHLW. The upper shielding layer USHL may be arranged between the pixel groups PG in the component area CA and may be provided in the form of an island. The upper shielding layer USHL may overlap the first wiring group WG1 and the second wiring group WG2. The transmission areas TA may be respectively arranged on a right side and a left side of the upper shielding layer USHL.

A constant voltage may be applied to the shielding layer SHL. For example, the shielding layer SHL may be electrically connected to a wiring configured to transmit the driving voltage ELVDD. Alternatively, the shielding layer SHL may be connected to the lower metal layer BML, such that a bias voltage applied to the lower metal layer BML may also be applied to the shielding layer SHL.

The shielding layer SHL may be provided to shield interference signals that may occur between the first wiring group WG1 and the second wiring group WG2. The first wiring group WG1 may be configured to receive data signals in a time period different from that of the second wiring group WG2. For example, the first wiring group WG1 may include data lines configured to receive data signals during a first period, and the second wiring group WG2 may include data lines configured to receive data signals during a second period.

If the shielding layer SHL is not arranged, when the first wiring group WG1 and the second wiring group WG2 are arranged adjacent to each other, a coupling phenomenon may occur in the second wiring group WG2 due to signals applied to the first wiring group WG1. Alternatively, a coupling phenomenon may occur in the first wiring group WG1 due to signals applied to the second wiring group WG2. Because the shielding layer SHL is arranged in the display apparatus according to the present embodiment, a coupling phenomenon between the first wiring group WG1 and the second wiring group WG2 may be prevented.

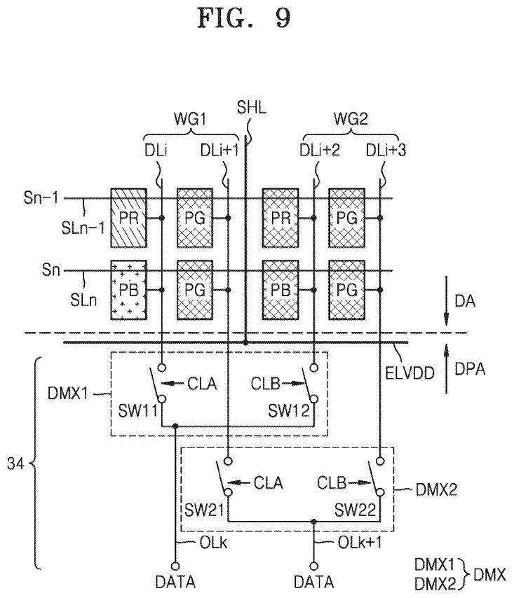

FIG. 9 is a diagram schematically showing an example of wiring groups that receive data signals by a data distribution unit.

Referring to FIG. 9, pixel circuits connected to an (n−1)^{th} scan line SLn−1 arranged in an (n−1)^{th} row and an n^{th} scan line SLn arranged in an n^{th} row may be arranged in the display area DA. The pixel circuits may be respectively configured to drive a first pixel PR, a second pixel PB, and a third pixel PG, which emit light of different colors from each other.

The data distribution unit 34 may be arranged in the peripheral area DPA or the display circuit board 30 (see FIG. 3). The data distribution unit 34 may include a plurality of demultiplexers DMX. The demultiplexers DMX may include first demultiplexers DMX1 and second demultiplexers DMX2. A first demultiplexer DMX1 may selectively connect a k^{th} output line OLk to an i^{th} data line DLi and an (i+2)^{th} data line DLi+2. A second demultiplexer DMX2 may selectively connect a (k+1)^{th} output line OLk+1 to an (i+1)^{th} data line DLi+1 and an (i+3)^{th} data line DLi+3.

The first demultiplexer DMX1 may include a first switch SW11 and a second switch SW12.

The first switch SW11 may be provided between the k^{th} output line OLk and the i^{th} data line DLi. The first switch SW11 may connect the k^{th} output line OLk to the i^{th} data line DLi according to a first control signal CLA and may apply, to the i^{th} data line DLi, a data signal DATA applied to the k^{th} output line OLk.

The second switch SW12 may be provided between the k^{th} output line OLk and the (i+2)^{th} data line DLi+2. The second switch SW12 may connect the k^{th} output line OLk to the (i+2)^{th} data line DLi+2 according to a second control signal CLB and may apply, to the (i+2)^{th} data line DLi+2, the data signal DATA applied to the k^{th} output line OLk.

The second demultiplexer DMX2 may include a first switch SW21 and a second switch SW22.

The first switch SW21 may be provided between the (k+1)^{th} output line OLk+1 and the (i+1)^{th} data line DLi+1. The first switch SW21 may connect the (k+1)^{th} output line OLk+1 to the (i+1)^{th} data line DLi+1 according to the first control signal CLA and may apply, to the (i+1)^{th} data line DLi+1, the data signal DATA applied to the (k+1)^{th} output line OLk+1.

The second switch SW22 may be provided between the (k+1)^{th} output line OLk+1 and the (i+3)^{th} data line DLi+3. The second switch SW22 may connect the (k+1)^{th} output line OLk+1 to the (i+3)^{th} data line DLi+3 according to the second control signal CLB and may apply, to the (i+3)^{th} data line DLi+3, the data signal DATA applied to the (k+1)^{th} output line OLk+1.

The i^{th} data line DLi and the (i+1)^{th} data line DLi+1 may be included in the first wiring group WG1. The data lines included in the first wiring group WG1 may be configured to receive the data signal DATA according to the first control signal CLA.

The (i+2)^{th} data line DLi+2 and the (i+3)^{th} data line DLi+3 may be included in the second wiring group WG2. The data lines included in the second wiring group WG2 may be configured to receive the data signal DATA according to the second control signal CLB.

The shielding layer SHL may be arranged between the first wiring group WG1 and the second wiring group WG2, and a constant voltage may be applied to the shielding layer SHL. The shielding layer SHL may include a plurality of shielding layers arranged in different layers from each other, and some of the shielding layers may be provided in the form of a wiring extending in the same direction as the data lines included in the first wiring group WG1 and the second wiring group WG2.

In the present embodiment, a coupling phenomenon that may occur between the first wiring group WG1 and the second wiring group WG2 may be reduced by the shielding layer SHL.

In an embodiment, the shielding layer SHL may be arranged only in a portion of the display area DA. For example, the shielding layer SHL may be arranged in the component area CA and may not be arranged in the main display area MDA. However, the disclosure is not limited thereto. The shielding layer SHL may be arranged in at least two areas among the component area CA, the main display area MDA, and the peripheral area DPA.

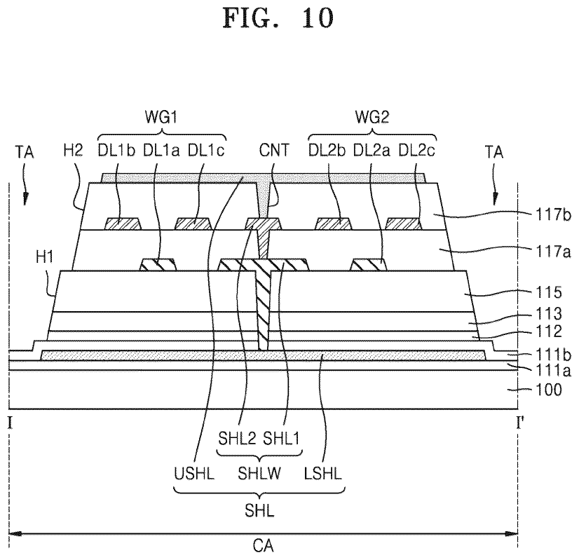

FIG. 10 is a cross-sectional view, taken along a line I-I′ of FIG. 8, showing a shielding layer according to an embodiment. In FIG. 10, the same reference numerals as those in FIGS. 7 and 8 denote the same members.

The shielding layer SHL according to the present embodiment may be arranged in the component area CA and may include a plurality of shielding layers. The shielding layer SHL may include the shielding wiring SHLW and the upper shielding layer USHL, which are arranged in different layers from each other. In addition, the shielding layer SHL may further include a lower shielding layer LSHL.

The shielding wiring SHLW may be arranged between the first wiring group WG1 and the second wiring group WG2. The first wiring group WG1 may be arranged on a left side of the shielding wiring SHLW, and the second wiring group WG2 may be arranged on a right side of the shielding wiring SHLW.

The first wiring group WG1 may include a first-1 data line DL1a, a first-2 data line DL1b, and a first-3 data line DL1c. The first-1, first-2, and first-3 data lines DL1a, DL1b, and DL1c may be configured to receive data signals according to the first control signal CLA applied to the data distribution unit 34 (see FIG. 9). At least some of the first-1, first-2, and first-3 data lines DL1a, DL1b, and DL1c may be arranged in different layers. The first-1 data line DL1a may be arranged on the interlayer insulating layer 115, and the first-2 data line DL1b and the first-3 data line DL1c may be arranged on the first planarization layer 117a. The data lines arranged in different layers may be alternately arranged relative to each other. For example, the first-1 data line DL1a may be arranged between the first-2 data line DL1b and the first-3 data line DL1c. This arrangement may minimize interference between adjacent data lines.

The second wiring group WG2 may include a second-1 data line DL2a, a second-2 data line DL2b, and a second-3 data line DL2c. The second-1, second-2, and second-3 data lines DL2a, DL2b, and DL2c may be configured to receive data signals according to the second control signal CLB applied to the data distribution unit 34 (see FIG. 9). At least some of the second-1, second-2, and second-3 data lines DL2a, DL2b, and DL2c may be arranged in different layers. The second-1 data line DL2a may be arranged on the interlayer insulating layer 115, and the second-2 data line DL2b and the second-3 data line DL2c may be arranged on the first planarization layer 117a. The data lines arranged in different layers may be alternately arranged relative to each other. For example, the second-1 data line DL2a may be arranged between the second-2 data line DL2b and the second-3 data line DL2c. This arrangement may minimize interference between adjacent data lines.

The shielding wiring SHLW may be arranged in the same layer as the data lines included in the first wiring group WG1 and the second wiring group WG2. The shielding wiring SHLW may include a first shielding line SHL1 and a second shielding line SHL2. The first shielding line SHL1 may be arranged on the interlayer insulating layer 115. The first shielding line SHL1 may be arranged in the same layer as the first-1 data line DL1a and the second-1 data line DL2a, and may include the same material as the first-1 data line DL1a and the second-1 data line DL2a. The second shielding line SHL2 may be arranged on the first planarization layer 117a. The second shielding line SHL2 may be arranged in the same layer as the first-2 and first-3 data lines DL1b and DL1c and the second-2 and second-3 data lines DL2b and DL2c, and may include the same material as the first-2 and first-3 data lines DL1b and DL1c and the second-2 and second-3 data lines DL2b and DL2c. The second shielding line SHL2 may be connected to the first shielding line SHL1 via a wiring contact hole extending through the first planarization layer 117a. The wiring contact hole is part of the contact hole CNT. The first shielding line SHL1 may at least partially overlap the second shielding line SHL2.

The upper shielding layer USHL may be arranged above the shielding wiring SHLW. The upper shielding layer USHL may be arranged on the second planarization layer 117b covering the second shielding line SHL2. The upper shielding layer USHL may be connected to the shielding wiring SHLW via an upper contact hole that is part of the contact hole CNT. The upper shielding layer USHL may be connected to the second shielding line SHL2 of the shielding wiring SHLW via the upper contact hole that extends through the second planarization layer 117b.

The upper shielding layer USHL may be arranged in the same layer as the first pixel electrode 121 (see FIG. 7), and may include the same material as the first pixel electrode 121 (see FIG. 7). In the present embodiment, the upper shielding layer USHL may at least partially overlap the first wiring group WG1 and the second wiring group WG2. The upper shielding layer USHL may be provided to overlap all the data lines included in the first wiring group WG1 and the second wiring group WG2. A coupling phenomenon between the first wiring group WG1, the second wiring group WG2, and external signals may be significantly reduced by the upper shielding layer USHL.

The lower shielding layer LSHL may be arranged under the shielding wiring SHLW. The lower shielding layer LSHL may be arranged between the first buffer layer 111a and the second buffer layer 111b. The lower shielding layer LSHL may be arranged in the same layer as the lower metal layer BML (see FIG. 7), and may include the same material as the lower metal layer BML (see FIG. 7). The lower shielding layer LSHL may be provided integrally with the lower metal layer BML, as a single body. The shielding wiring SHLW may be connected to the lower shielding layer LSHL via a lower contact hole that is part of the contact hole CNT. The lower shielding layer LSHL may at least partially overlap the first wiring group WG1 and the second wiring group WG2. The first shielding line SHL1 may be connected to the lower shielding layer LSHL via the lower contact hole that extends through at least one of the interlayer insulating layer 115, the second gate insulating layer 113, the first gate insulating layer 112, and the second buffer layer 111b.

The lower shielding layer LSHL, the shielding wiring SHLW, and the upper shielding layer USHL may be connected to each other, and a constant voltage may be applied thereto. Accordingly, because an area between the first wiring group WG1 and the second wiring group WG2 and areas above and under the first wiring group WG1 and the second wiring group WG2 are electrically blocked by the shielding layers, a coupling phenomenon occurring between the first wiring group WG1 and the second wiring group WG2 may be minimized.

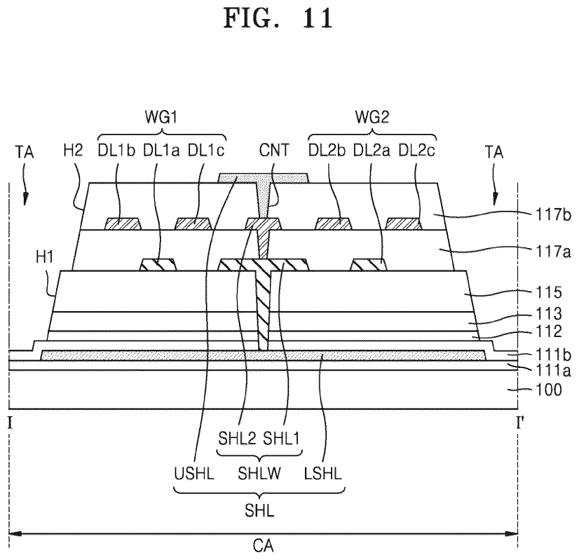

FIGS. 11 to 15 show shielding layers according to various embodiments. In FIGS. 11 to 15, the same reference numerals as those in FIG. 10 denote the same members.

The shielding layer SHL according to the present embodiment may be arranged in the component area CA and may include a plurality of shielding layers. The shielding layer SHL may be at least partially arranged between the first wiring group WG1 and the second wiring group WG2. The shielding layer SHL may receive a constant voltage.

Referring to FIG. 11, the shielding layer SHL may include the lower shielding layer LSHL, the shielding wiring SHLW, and the upper shielding layer USHL. The lower shielding layer LSHL, the shielding wiring SHLW, and the upper shielding layer USHL may overlap each other and may be connected to each other via the upper contact hole.

In the present embodiment, the upper shielding layer USHL may not overlap the first wiring group WG1 and/or the second wiring group WG2. Because the upper shielding layer USHL is arranged in the same layer as the first pixel electrode 121 or the second pixel electrode 121′ (see FIG. 7), the upper shielding layer USHL may be designed not to overlap the first wiring group WG1 and/or the second wiring group WG2.

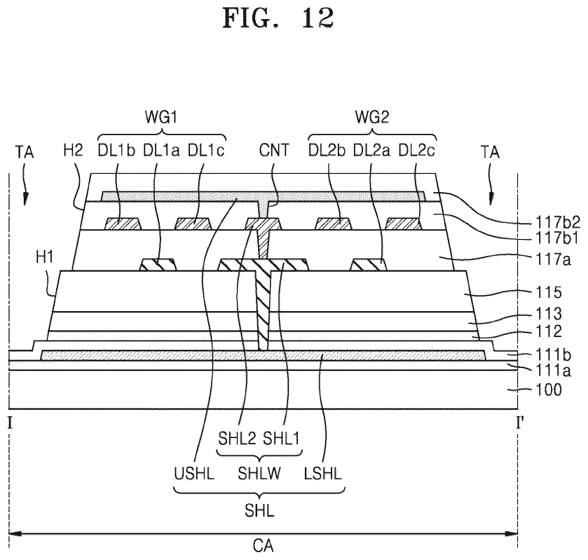

Referring to FIG. 12, the shielding layer SHL may include the lower shielding layer LSHL, the shielding wiring SHLW, and the upper shielding layer USHL. The lower shielding layer LSHL, the shielding wiring SHLW, and the upper shielding layer USHL may overlap each other and may be connected to each other via the contact hole CNT. The contact hole CNT may include the lower contact hole, the wiring contact hole, and the upper contact hole.

The second planarization layer 117b may be provided by stacking a second-1planarization layer 117b1 and a second-2 planarization layer 117b2. The second-1 planarization layer 117b1 may include an inorganic insulating material such as silicon oxide (SiO₂), silicon nitride (SiNₓ), or silicon oxynitride (SiON). The second-2 planarization layer 117b2 may include an organic insulating material such as BCB, polyimide, photosensitive polyimide (PSPI), HMDSO, PMMA, or PS.

In the present embodiment, the upper shielding layer USHL may be arranged on the second-1 planarization layer 117b1, and the second-2 planarization layer 117b2 may be arranged to cover the upper shielding layer USHL. A pixel electrode may be arranged on the second-2 planarization layer 117b2. In other words, the upper shielding layer USHL may not be arranged in the same layer as the pixel electrode. Because the upper shielding layer USHL is arranged in a different layer from the pixel electrode, design freedom of the upper shielding layer USHL may be increased. In addition, because the upper shielding layer USHL is arranged close to the data lines included in the first wiring group WG1 and the second wiring group WG2, a shielding effect may be enhanced.

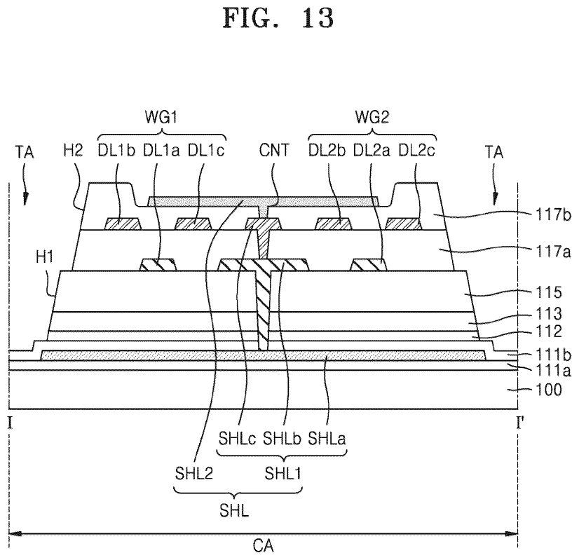

Referring to FIG. 13, the shielding layer SHL may include the lower shielding layer LSHL, the shielding wiring SHLW, and the upper shielding layer USHL. The lower shielding layer LSHL, the shielding wiring SHLW, and the upper shielding layer USHL may overlap each other and may be connected to each other via the contact hole CNT.

In the present embodiment, the second planarization layer 117b may include areas having different thicknesses from each other. In an area where the upper shielding layer USHL is arranged, the thickness of the second planarization layer 117b may be small. The second planarization layer 117b may include PSPI and thus may have areas of different thicknesses formed by a halftone mask process.

The upper shielding layer USHL may at least partially overlap the data lines included in the first wiring group WG1 and the second wiring group WG2. In the drawing, it is shown that the upper shielding layer USHL overlaps the first-1 data line DL1a and the first-3 data line DL1c of the first wiring group WG1 and the second-1 data line DL2a and the second-2 data line DL2b of the second wiring group WG2, but the disclosure is not limited thereto. The upper shielding layer USHL may be formed to cover all the data lines included in the first wiring group WG1 and the second wiring group WG2.

Due to this structure, the upper shielding layer USHL may be arranged close to the data lines included in the first wiring group WG1 and the second wiring group WG2, and thus, a shielding effect may be enhanced.

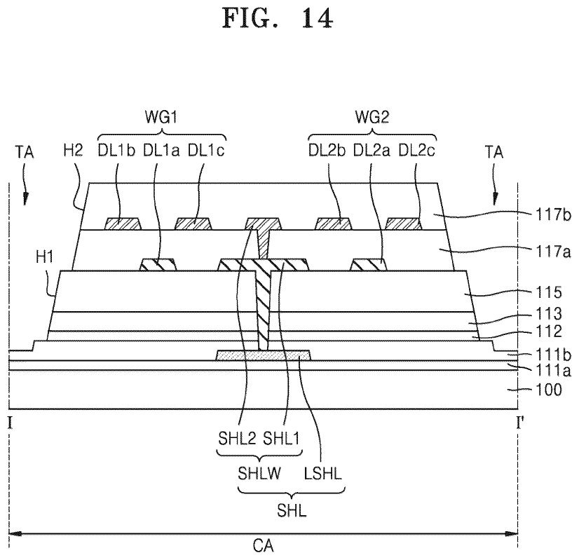

Referring to FIG. 14, the shielding layer SHL may include the lower shielding layer LSHL and the shielding wiring SHLW. The lower shielding layer LSHL and the shielding wiring SHLW may overlap each other and may be connected to each other via the contact hole CNT, such as the lower contact hole.

In the present embodiment, the upper shielding layer USHL may not be arranged, and the lower shielding layer LSHL may not overlap the first wiring group WG1 and the second wiring group WG2. When a coupling phenomenon between the first wiring group WG1 and the second wiring group WG2 is not significant, the shielding layer SHL may be implemented in various modified forms, such as including only the lower shielding layer LSHL and the shielding wiring SHLW.

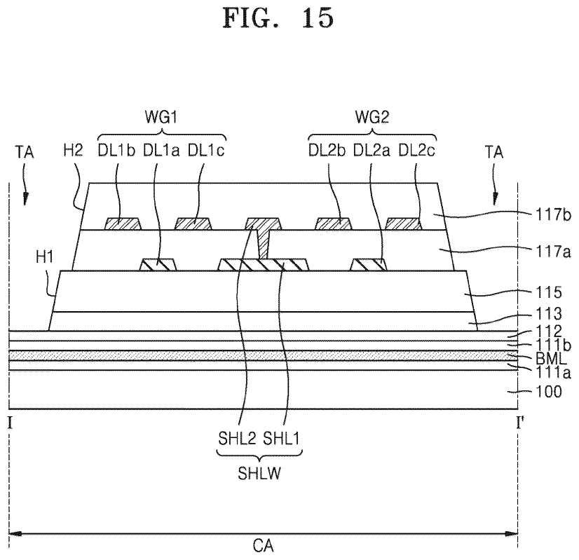

Referring to FIG. 15, the shielding layer SHL may include the shielding wiring SHLW in which the first shielding line SHL1 and the second shielding line SHL2 are stacked. The first shielding line SHL1 and the second shielding line SHL2 may overlap each other and may be connected to each other via the contact hole CNT, such as the wiring contact hole. In this case, the shielding wiring SHLW may overlap the lower metal layer BML, but may not be connected to the lower metal layer BML via a contact hole.

When a coupling phenomenon between the first wiring group WG1 and the second wiring group WG2 is not significant, the shielding layer SHL may be implemented in various modified forms, such as including only the shielding wiring SHLW in which the first shielding line SHL1 and the second shielding line SHL2 are stacked.

The embodiments described with reference to FIGS. 10 to 15 may be implemented in various ways, such as individually or as a combination. The display apparatus according to the above-described embodiment may be applied to various electronic apparatuses. An electronic apparatus according to an embodiment may include the above-described display apparatus, and may further include a module or apparatus having other additional functions, in addition to the display apparatus.

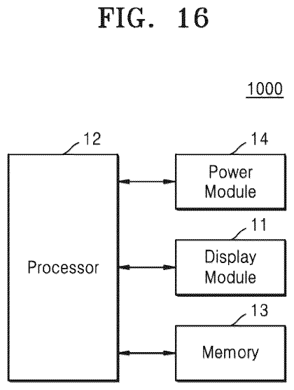

FIG. 16 is a block diagram of an electronic apparatus according to an embodiment. Referring to FIG. 16, an electronic apparatus 1000 according to an embodiment may include a display module 11, a processor 12, a memory 13, and a power module 14.

The processor 12 may include at least one of a central processing unit (CPU), an application processor (AP), a graphics processing unit (GPU), a communication processor (CP), an image signal processor (ISP), and a controller.

The memory 13 may store data information required to operate the processor 12 or the display module 11. When the processor 12 executes an application stored in the memory 13, an image data signal and/or an input control signal may be transmitted to the display module 11, and the display module 11 may process the received signal and output image information via a display screen.

The power module 14 may include a power supply module, such as a power adapter or a battery apparatus, and a power conversion module that converts power supplied by the power supply module and generates power required to operate the electronic apparatus 1000.

At least one of the components of the electronic apparatus 1000 may be included in the display apparatus according to the above-described embodiments. In addition, some individual modules functionally included within one module may be included in the display apparatus, and other individual modules may be provided separately from the display apparatus. For example, the display apparatus may include the display module 11, and the processor 12, the memory 13, and the power module 14 may be provided in the form of other apparatuses within the electronic apparatus 1000 other than the display apparatus.

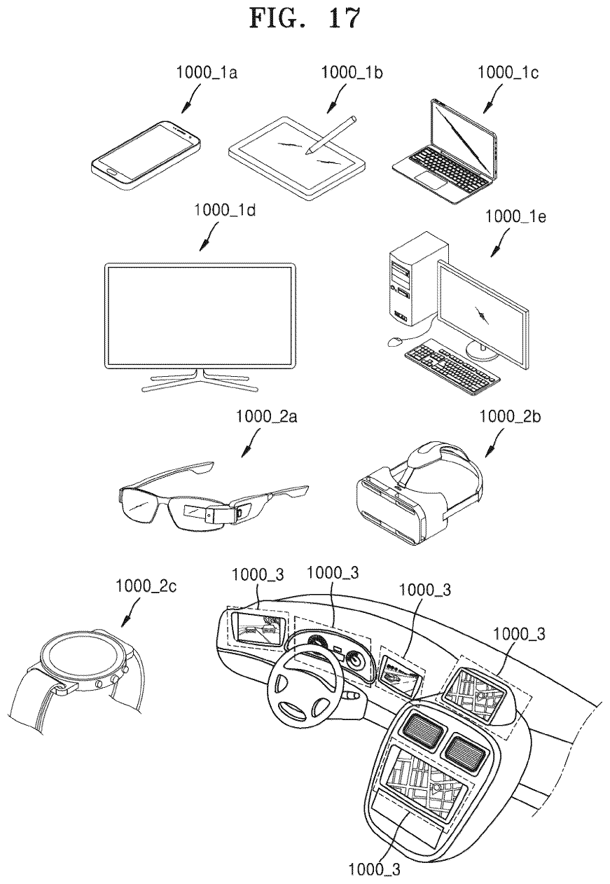

FIG. 17 shows schematic views of electronic apparatuses according to various embodiments.

Referring to FIG. 17, various electronic apparatuses, to which the display apparatus according to the embodiments is applied, may include not only image display electronic apparatuses, such as a smartphone 1000_1a, a tablet PC 1000_1b, a laptop 1000_1c, a TV 1000_1d, and a desk monitor 1000_1e, but also wearable electronic apparatuses including a display module, such as smart glasses 1000_2a, a head-mounted display 1000_2b, and a smart watch 1000_2c, as well as vehicle electronic apparatuses 1000_3 including a display module, such as an instrument panel of a vehicle, a center fascia, a center information display (CID) arranged on a dashboard, and a room mirror display.

As described above, the display apparatus according to the present embodiments has densely arranged therein wirings passing between pixel groups in a component area and has arranged therein a shielding layer between the pixel groups, thereby securing a large transmission area to improve transmittance and simultaneously minimize interference between wiring signals.

However, the scope of the disclosure is not limited thereto.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a substrate comprising a first display area and a second display area, the second display area having a transmission area;
first pixel circuits and first display elements in the first display area;
second pixel circuits and second display elements on the substrate in the second display area, the second pixel circuits and the second display elements being part of pixel groups that are spaced apart from each other with the transmission area therebetween;
a first wiring group and a second wiring group disposed at least partially between the pixel groups in the second display area; and
a shielding layer in the second display area and, in a plan view, arranged between the first wiring group and the second wiring group.

2. The display apparatus of claim 1, wherein the first wiring group and the second wiring group are connected to demultiplexers that operate according to a first control signal and a second control signal,
the first wiring group comprises a first data line through which a data signal is transmitted according to the first control signal, and
the second wiring group comprises a second data line through which a data signal is transmitted according to the second control signal.

3. The display apparatus of claim 1, wherein the shielding layer comprises a shielding wiring and an upper shielding layer that are arranged one on top of the other in different layers and are connected to each other via an upper contact hole.

4. The display apparatus of claim 3, wherein the shielding wiring extends in one direction in the second display area, and
the upper shielding layer extends in a direction that is orthogonal to the one direction.

5. The display apparatus of claim 3, wherein the upper shielding layer at least partially overlaps the first wiring group and the second wiring group.

6. The display apparatus of claim 3, wherein the shielding wiring comprises a first shielding line and a second shielding line, the second shielding line being arranged in a different layer from the first shielding line and connected to the first shielding line via a wiring contact hole, wherein the first shielding line overlaps the second shielding line.

7. The display apparatus of claim 3, wherein the shielding layer further comprises a lower shielding layer arranged under the shielding wiring, and the shielding wiring is connected to the lower shielding layer via a lower contact hole.

8. The display apparatus of claim 3, wherein the upper shielding layer is arranged in a same layer as pixel electrodes of the second display elements.

9. The display apparatus of claim 3, further comprising:
a second-1 planarization layer arranged between the shielding wiring and the upper shielding layer and comprising an inorganic insulating material; and
a second-2 planarization layer covering the upper shielding layer and comprising an organic insulating material,
wherein the pixel electrodes of the second display elements are arranged on the second-2 planarization layer.

10. The display apparatus of claim 3, further comprising a second planarization layer arranged between the shielding wiring and the upper shielding layer, wherein the second planarization layer is thinner in an area where the upper shielding layer is arranged than in other areas.

11. The display apparatus of claim 1, wherein the shielding layer comprises a shielding wiring comprising a first shielding line and a second shielding line that are arranged one on top of the other in different layers and are connected to each other via a wiring contact hole.

12. The display apparatus of claim 11, wherein the shielding layer further comprises a lower shielding layer under the shielding wiring, the second shielding line being connected to the lower shielding layer via a lower contact hole.

13. The display apparatus of claim 1, wherein a constant voltage is applied to the shielding layer.

14. The display apparatus of claim 1, wherein the shielding layer is provided by a lower shielding layer, a shielding wiring, and an upper shielding layer in an overlapping arrangement wherein the shielding wiring extends in one direction between the first wiring group and the second wiring group.

15. The display apparatus of claim 14, further comprising a lower metal layer arranged between the substrate and the second pixel circuits, wherein the lower shielding layer is integrated with the lower metal layer.

16. An electronic apparatus comprising a display apparatus, wherein the display apparatus comprises:
a substrate comprising a first display area and a second display area, the second display area having a transmission area;
first pixel circuits and first display elements in the first display area;
second pixel circuits and second display elements on the substrate in the second display area, the second pixel circuits and the second display elements being part of pixel groups that are spaced apart from each other with the transmission area therebetween;
a first wiring group and a second wiring group, the second wiring group extending between the pixel groups in the second display area; and
a shielding layer in the second display area and, in a plan view, arranged between the first wiring group and the second wiring group.

17. The electronic apparatus of claim 16, wherein the shielding layer is provided by arranging a shielding wiring and an upper shielding layer on top of each other,
wherein the shielding wiring extends in one direction between the first wiring group and the second wiring group.

18. The electronic apparatus of claim 17, wherein the upper shielding layer extends in a direction orthogonal to the one direction.

19. The electronic apparatus of claim 17, wherein the shielding layer further comprises a lower shielding layer arranged under the shielding wiring.

20. The electronic apparatus of claim 16, wherein the first wiring group and the second wiring group are connected to demultiplexers that operate according to a first control signal and a second control signal,
the first wiring group comprises a first data line through which a data signal is transmitted according to the first control signal, and
the second wiring group comprises a second data line through which a data signal is transmitted according to the second control signal.
